(19) United States
(12) Patent Application Publication
(10) Pub. No.: US 2021/0376189 A1
(43) Pub. Date: Dec. 2, 2021

(54) MASS TRANSFER DEVICE, MASS TRANSFER METHOD, AND STORAGE MEDIUM

(71) Applicant: CHONGQING KONKA PHOTOELECTRIC TECHNOLOGY RESEARCH INSTITUTE CO., LTD., Chongqing (CN)

(72) Inventor: Guangping JIANG, Chongqing (CN)

(21) Appl. No.: 17/347,273

(22) Filed: Jun. 14, 2021

Related U.S. Application Data
(63) Continuation of application No. PCT/CN2020/092913, filed on May 28, 2020.

(51) Int. Cl. H01L 33/00; G02B 6/42; G02B 19/00; B23K 26/06; B23K 26/082; B23K 26/53; G05B 19/4155

(52) U.S. Cl. CPC H01L 33/0095; G02B 6/4204; G02B 19/0009; G02B 19/0047; B23K 2103/56; B23K 26/082; B23K 26/53; G05B 19/4155; B23K 26/0665

(57) ABSTRACT

Disclosed are a mass transfer device and a mass transfer method. The mass transfer device includes a laser (100), a coupling unit (200), an optical fiber (300), a ceramic ferrule (400), and a coaxial focusing structure (500) which are sequentially connected. A laser light output by the laser (100) is coupled into the optical fiber (300) through the coupling unit (200). The coaxial focusing structure (500) is fixed to an end of the ceramic ferrule (400). An end of the optical fiber (300) is inserted into the ceramic ferrule (400).

### CROSS-REFERENCE TO RELATED APPLICATION (S)

This application is a continuation of International Application No. PCT/CN2020/092913, filed on May 28, 2020, the disclosure of which is hereby incorporated by reference in its entirety.

### TECHNICAL FIELD

The disclosure relates to the technical field of Light Emitting Diodes (LEDs), and more particularly, to a mass transfer device, a mass transfer method, and a storage medium.

### BACKGROUND

A Micro Light Emitting Diode (Micro-LED) technology is a new generation of display technology. Compared with a related Organic Light-Emitting Diode (OLED) technology, the Micro-LED technology has higher brightness, better light-emitting effect and lower power consumption. The Micro-LED technology, i.e. an LED miniaturizing and matrix technology, refers to a high-density micro-sized micro edition integrated on a chip, which reduces a pixel point distance from millimeter to micrometer. However, in the Micro-LED technology, a miniature LED manufacturing process includes: firstly, designing an LED structure to be thin-film, micro and arrayed, so that the size of the LED structure is about 1-250 μm; then, transferring red, green and blue miniature LED micro-components to a circuit substrate in batches; then, implementing a protective layer and a top electrode by using a physical deposition method; and finally, packaging a top substrate. The transferring LED micro-components to a circuit substrate in batches is critical.

At present, a laser lift-off technology is generally used for carrying out Micro-LED mass transfer. An LED assembly to be transferred includes a release layer, an adhesive layer, an LED chip, a first temporary substrate, and a second temporary substrate. The release layer may be formed by using, for example, a fluorine coating, silicone, a water-soluble adhesive (e.g., PVA), and polyimide. A laser light selectively irradiates the release layer at the position of the LED to be transferred to cause viscosity loss or direct vaporization, so that the LED to be transferred is lifted off from the first temporary substrate and adhered to the second temporary substrate.

The current laser lift-off technology used in Micro-LED is a galvanometer scanning mode, the position of a light spot is controlled by controlling reflectors in an X axis and a Y axis, and the technology is sensitive to external vibration, stress and motor precision, so that it is difficult to accurately control the track of the light spot.

Therefore, how to improve the accuracy of spot control in the laser lift-off technology is a problem to be solved.

### SUMMARY

According to a first aspect, the disclosure provides a mass transfer device, including: a laser, a coupling unit, an optical fiber, a ceramic ferrule, and a coaxial focusing structure which are sequentially connected. A laser light output by the laser is coupled into the optical fiber through the coupling unit, the coaxial focusing structure is fixed to an end of the ceramic ferrule, and an end of the optical fiber is inserted into the ceramic ferrule.

Further, the coupling unit includes a lens assembly, wherein the lens assembly is an assembly composed of one or more lenses.

Further, the coaxial focusing structure is used to focus a laser beam propagating in the optical fiber at a point on a substrate carrying LEDs to be lifted off.

Further, the outer side of the coaxial focusing structure is provided with a first supporting rod and a second supporting rod perpendicular to each other, a telescopic sliding rod is connected to a tail end of the second supporting rod, one end of the telescopic sliding rod is vertically fixed with the second supporting rod, and the other end of the telescopic sliding rod is vertically fixed with a rotating rod of a motor.

Further, the telescopic sliding rod includes a telescopic driving assembly, and the length of the telescopic sliding rod is adjusted through the telescopic driving assembly.

Further, the mass transfer device further includes: a processor, where the laser, the telescopic sliding rod and the motor are connected to the processor respectively.

The processor is configured to send a first scanning signal to the motor to control a rotating speed of the motor through the first scanning signal.

The processor is further configured to send a second scanning signal to the telescopic sliding rod to adjust the length of the telescopic sliding rod through the second scanning signal, so as to adjust a spiral rotation radius of the coaxial focusing structure.

The processor is further configured to send a laser pulse signal to the laser to control the laser to emit a laser light through the laser pulse signal.

Further, the laser is an electrically controlled laser.

According to a second aspect, the disclosure further provides a mass transfer method based on the mass transfer device of the first aspect. The mass transfer method includes the following.

The first scanning signal is sent to the motor of the mass transfer device, and the rotating speed of the motor is controlled through the first scanning signal.

The second scanning signal is sent to the telescopic sliding rod of the mass transfer device, and the spiral rotation radius of the coaxial focusing structure in the mass transfer device is adjusted through the second scanning signal.

The laser pulse signal is sent to the laser of the mass transfer device in cooperation with the first scanning signal, and the laser is controlled to emit the laser light through the laser pulse signal.

Further, the operation that the spiral rotation radius of the coaxial focusing structure in the mass transfer device is adjusted through the second scanning signal includes the following operation.

The telescopic driving assembly of the telescopic sliding rod is controlled to telescopically move through the second scanning signal, the telescopic sliding rod is driven to slide, and the spiral rotation radius of the coaxial focusing structure in the mass transfer device is adjusted.

Further, after the laser is controlled to emit the laser light through the laser pulse signal, the method further includes the following.

The laser light is coupled through the coupling unit of the mass transfer device, and the coupled laser light is transmitted into the optical fiber of the mass transfer device.

The laser beam propagating in the optical fiber is focused on the substrate carrying the LEDs to be lifted off through the coaxial focusing structure of the mass transfer device.

According to a third aspect, the disclosure further provides a non-transitory computer readable storage medium. The non-transitory computer readable storage medium is configured to store a computer program which, when executed by a processor, causes the processor to execute the transfer method of the first aspect.

### BRIEF DESCRIPTION OF THE DRAWINGS

FIG. 1 is a schematic diagram illustrating Micro-LED mass transfer using a laser lift-off technology in a related art.

FIG. 2 is a schematic diagram illustrating an overall structure of a mass transfer device according to an embodiment of the disclosure.

FIG. 3 is a flowchart illustrating a mass transfer method according to an embodiment of the disclosure.

FIG. 4 is a schematic diagram illustrating a laser scanning track when the length of a telescopic sliding rod is gradually changed according to an embodiment of the disclosure.

FIG. 5 is a schematic diagram illustrating a laser scanning track when the length of a telescopic sliding rod is intermittently changed according to an embodiment of the disclosure.

In the figures: 1, first substrate; 3, Micro-LED; 4, second substrate; 5, masking plate; 6, adhesive layer; 8, release layer; 9, laser light; 100, laser; 200, coupling unit; 300, optical fiber; 400, ceramic ferrule; 500, coaxial focusing structure; 510, focusing lens; 610, first supporting rod; 620, second supporting rod; 700, telescopic sliding rod; 800, motor; 810, rotating shaft; 900, substrate for lift-off.

### DETAILED DESCRIPTION

The disclosure will now be described in further detail with reference to the accompanying drawings.

The present specific embodiment is merely illustrative of the disclosure and is not intended to be limiting of the disclosure. Those skilled in the art, after reading the present specification, may, on demand, make modifications to the present embodiment without inventive contribution, provided they are protected by patent laws within the scope of the claims of the disclosure.

In the description of the disclosure, it is to be understood that the orientations or positional relationships indicated by terms “length”, “width”, “upper”, “lower”, “front”, “rear”, “left”, “right”, “vertical”, “horizontal”, “top”, “bottom”, “inner”, “outer” and the like are the orientations or positional relationships shown in the drawings, and are only for the convenience of describing the disclosure and simplifying the description, rather than indicating or implying that devices or elements must have a specific orientation and must be constructed and operated in a specific orientation, and therefore it should not be construed as limiting the disclosure.

In addition, terms “first”, “second” and “third” are only adopted for description and should not be understood to indicate or imply relative importance or implicitly indicate the number of indicated technical features. Therefore, a feature defined by “first”, “second” and “third” may explicitly or implicitly indicate inclusion of one or more of such features. In the description of the disclosure, “multiple” means two or more, unless otherwise limited definitely and specifically.

In the disclosure, unless otherwise specified and limited, “mounted”, “connected to”, “connected”, “fixed”, “arranged”, and other terms should be generally understood. For example, the term may be fixed connection or detachable connection or integral connection, the term may be mechanical connection or electrical connection, and the term may be direct connection or indirect connection through an intermediate or communication inside two elements or interaction between two elements. Those of ordinary skill in the art can understand specific implications of the above terms in the disclosure in specific situations.

### Embodiment 1

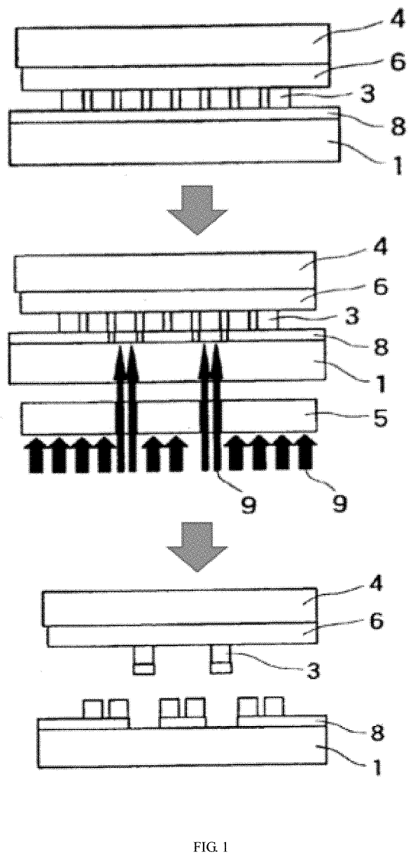

As shown in FIG. 1, in a related MICRO-LED mass transfer technology using a laser lift-off technology in the related art, a release layer 8 is a liftoff layer formed by a fluorine coating, silicone, a water-soluble adhesive (e.g., PVA), polyimide, etc. When a MICRO-LED on a first substrate 1 need to be transferred, a laser light 9 may be selectively irradiated on the release layer 8 at the position of the MICRO-LED to be transferred, so that the release layer 8 loses viscosity or is directly vaporized, the MICRO-LED to be transferred is lifted off from the first substrate 1 and adhered to a second substrate 4, and the mass transfer of the MICRO-LED is implemented.

At present, in a laser lift-off technology of Micro LED, a scanning mode generally adopted is a galvanometer scanning mode, and the position of a laser spot is controlled by controlling scanning mirrors in an X axis and a Y axis, where a scanning mirror X and a scanning mirror Y are two reflectors, and reflection angles of the two reflectors are controlled by a galvanometer X and a galvanometer Y respectively, so that an angle of an incident beam to a field mirror may be controlled, and the position of a focusing point on a marking piece may be changed. However, the galvanometer scanning mode has extremely high requirements on external vibration, stress and motor precision, so that it is difficult to accurately control the track of the laser spot.

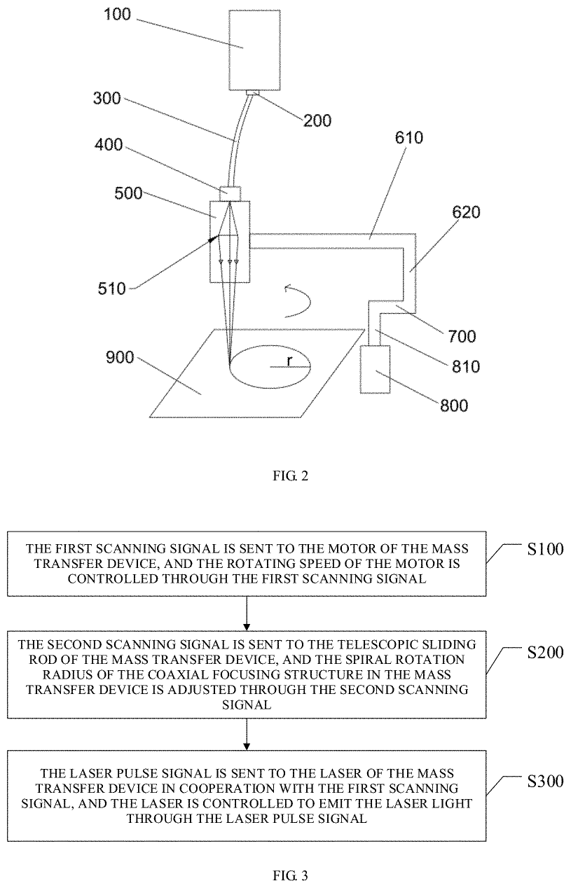

As shown in FIG. 2, in order to accurately control the track of a laser spot, the present embodiment provides a mass transfer device. The mass transfer device includes a laser 100, a coupling unit 200, an optical fiber 300, a ceramic ferrule 400, and a coaxial focusing structure 500 which are sequentially connected, where the coaxial focusing structure 500 is fixed to an end of the ceramic ferrule 400, and an end of the optical fiber 300 is inserted into the ceramic ferrule 400.

In the present embodiment, the laser 100 is an electrically controlled laser emitter, and the size of light beam energy output by the laser 100 may be controlled through a corresponding electric signal. A laser light output by the laser 100 enters the optical fiber 300 through a coupling action of the coupling unit 200 and then enters the coaxial focusing structure 500 through the conduction of the optical fiber 300. The laser light emitted by the laser 100 is focused on a substrate 900 carrying a MICRO-LED to be lifted off by means of a focusing action of the coaxial focusing structure 500, so that the mass transfer of the MICRO-LED is implemented by means of the laser light emitted by the laser 100.

In the present embodiment, the coupling unit 200 includes: a lens assembly (not shown), where the lens assembly may be a single spherical mirror or an assembly composed of multiple spherical mirrors. The lens assembly may also be a single aspheric mirror or an assembly composed of multiple aspheric mirrors. The lens assembly and the composition mode thereof belong to the related art and will not be described in detail.

In the present embodiment, the coaxial focusing structure 500 includes: a focusing lens 510. The focusing lens 510 may be used to focus a laser beam propagating in the optical fiber 300 at a point on the substrate 900 carrying the MICRO-LED to be lifted off, thereby transferring the MICRO-LED at the point on the substrate 900 for lift-off.

In the present embodiment, a first supporting rod 610 and a second supporting rod 620 are arranged on the outer side of the coaxial focusing structure 500, the first supporting rod 610 and the second supporting rod 620 are perpendicular to each other, a telescopic sliding rod 700 is connected to a tail end of the second supporting rod 620, one end of the telescopic sliding rod 700 is vertically fixed with the second supporting rod 620, and the other end of the telescopic sliding rod 700 is vertically fixed with a rotating rod 810 of a motor 800.

The motor 800 may be used to drive the coaxial focusing structure 500 to spirally rotate, and meanwhile, a spiral rotation radius of the coaxial focusing structure 500 may be adjusted by adjusting the length of the telescopic sliding rod 700 during the spiral rotation of the coaxial focusing structure 500.

In the present embodiment, the telescopic sliding rod 700 includes: a telescopic driving assembly (not shown), which may be a telescopic motor. The telescopic motor is controlled to rotate to drive the telescopic sliding rod 700 to telescopically move, so that the length of the telescopic sliding rod 700 is adjusted. When the telescopic sliding rod 700 telescopically moves, the spiral rotation radius of the coaxial focusing structure 500 may be adjusted by means of the telescopic sliding rod 700.

In the present embodiment, the mass transfer device further includes: a processor (not shown). The laser 100, the telescopic sliding rod 700 and the motor 800 are connected to the processor respectively. The processor may be used to send a first scanning signal to the motor 800 to control a rotating speed of the motor 800 through the first scanning signal, thereby controlling a spiral rotation speed of the coaxial focusing structure 500.

In the present embodiment, the processor is further used to send a second scanning signal to the telescopic motor (i.e., telescopic driving assembly) of the telescopic sliding rod 700 to control the telescopic motor to rotate through the second scanning signal, so as to drive the telescopic sliding rod 700 to telescopically move, and adjust the length of the telescopic sliding rod 700. Therefore, when the telescopic sliding rod 700 telescopically moves, the spiral rotation radius of the coaxial focusing structure 500 is adjusted by means of the telescopic sliding rod 700.

In the present embodiment, the processor is further configured to send a laser pulse signal to the laser 100 so as to control the laser 100 to emit a laser light through the laser pulse signal. When the processor sends the first scanning signal, the laser pulse signal is output in cooperation with the first scanning signal.

When the laser track moves to the position of a MICRO-LED chip to be transferred, the laser 100 is controlled to light and emit a laser beam through the laser pulse signal, so that the MICRO-LED chip to be transferred is separated from the substrate. When the laser track moves to the positions of other MICRO-LED chips which do not need to be transferred, the sending of the laser pulse signal is stopped, and the laser 100 is turned off, so that the MICRO-LED chips which do not need to be transferred may continuously stay on the substrate.

In the present embodiment, the focus position of laser output is determined only by the motor 800, and likewise, the position accuracy of the laser output is determined by the accuracy of the motor 800. Normally, the accuracy of the driving motor 800 has met the position accuracy requirement of lifting off the MICRO-LED chip.

The diameter of an output head of the coaxial focusing structure 500 is less than 5 mm or less than 10 mm, and when the spiral motion of the coaxial focusing structure 500 is controlled, the light-weight coaxial focusing structure 500 can more easily control the movement track thereof.

In the present embodiment, the end of the optical fiber is directly inserted into the ceramic ferrule, and the movement track of the laser scanning can be accurately controlled by mechanically controlling the movement track of an output light spot of the ceramic ferrule. In addition, by utilizing the assemblies such as the motor, the supporting rods, and the lenses, laser convergence and circular motion are realized, and the radius of the circular motion is controlled by utilizing the telescopic sliding rod, so that the spiral track of laser scanning is realized, and an ideal movement effect is achieved.

### Embodiment 2

As shown in FIG. 3, the present embodiment provides a mass transfer method based on the mass transfer device in Embodiment 1, where the mass transfer method includes the following.

At S100, the first scanning signal is sent to the motor of the mass transfer device, and the rotating speed of the motor is controlled through the first scanning signal.

At S200, the second scanning signal is sent to the telescopic sliding rod of the mass transfer device, and the spiral rotation radius of the coaxial focusing structure in the mass transfer device is adjusted through the second scanning signal.

At S300, the laser pulse signal is sent to the laser of the mass transfer device in cooperation with the first scanning signal, and the laser is controlled to emit the laser light through the laser pulse signal.

In the present embodiment, when the spiral rotation radius of the coaxial focusing structure is adjusted, the second scanning signal may be sent to the telescopic driving assembly of the telescopic sliding rod, the telescopic driving assembly of the telescopic sliding rod is controlled to telescopically move through the second scanning signal, and the telescopic sliding rod is driven to slide (telescopically move) to adjust the length of the telescopic sliding rod, so that the spiral rotation radius of the coaxial focusing structure in the mass transfer device is adjusted.

In the present embodiment, the first scanning signal and the second scanning signal may be sent simultaneously, i.e., the movement radius of the coaxial focusing structure may be adjusted simultaneously while controlling the rotating speed of the motor.

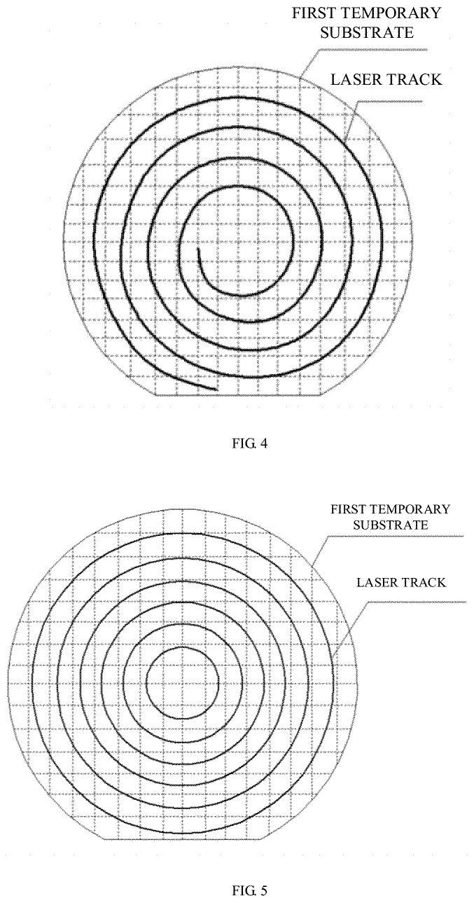

As shown in FIG. 4, when the first scanning signal is continuously output and the second scanning signal is continuously output, the telescopic sliding rod of the mass transfer device is gradually lengthened. At this moment, the movement track of the laser spot on the substrate carrying the MICRO-LED to be lifted off is a spiral movement track.

In the present embodiment, the first scanning signal and the second scanning signal may also be alternately sent, i.e., after controlling the rotating speed of the motor, the rotation control of the motor is stopped, and the second scanning signal is output.

As shown in FIG. 5, when the first scanning signal and the second scanning signal are alternately output, the first scanning signal is firstly output to control the motor to rotate, and when the motor completes one rotation period (i.e., the laser scanning track is a circular motion track), the output of the first scanning signal is stopped, and the second scanning signal is output to control the telescopic sliding rod to change the length. At this moment, the movement track of the laser spot on the substrate to be stripped of the MICRO-LED is a circular movement track.

In the present embodiment, after the laser emits a laser light, the laser light may be coupled through the coupling unit of the mass transfer device, and the coupled laser light may be transmitted into the optical fiber of the mass transfer device. Then, a laser beam propagating in the optical fiber is focused on the substrate carrying the MICRO-LED to be lifted off through the coaxial focusing structure of the mass transfer device.

When the laser track moves to the position of a MICRO-LED chip to be transferred, the laser is controlled to light and emit a laser beam through the laser pulse signal, so that the MICRO-LED chip to be transferred is separated from the substrate. When the laser track moves to the positions of other MICRO-LED chips which do not need to be transferred, the sending of the laser pulse signal is stopped, and the laser is turned off, so that the MICRO-LED chips which do not need to be transferred may continuously stay on the substrate.

In summary, the coaxial focusing structure is controlled by the motor and the telescopic sliding rod, and a spiral laser scanning track is implemented, so that a movement track of laser scanning is controlled in a high-precision manner, and the transfer efficiency and yield of Micro-LED are improved.

In an embodiment, the disclosure further provides a non-transitory computer readable storage medium. The non-transitory computer readable storage medium is configured to store a computer program which, when executed by a processor, causes the processor to execute the above mass transfer method.

It is to be understood that the disclosure is not limited in its application to the examples described above and that improvements or variations may be made in light of the above teachings by those of ordinary skill in the art, all falling within the scope of the appended claims of the disclosure.

What is claimed is:

1. A mass transfer device, comprising: a laser, a coupling unit, an optical fiber, a ceramic ferrule, and a coaxial focusing structure which are sequentially connected, wherein a laser light output by the laser is coupled into the optical fiber through the coupling unit, the coaxial focusing structure is fixed to an end of the ceramic ferrule, and an end of the optical fiber is inserted into the ceramic ferrule.

2. The mass transfer device according to claim 1, wherein the coupling unit comprises a lens assembly, wherein the lens assembly is an assembly composed of one or more lenses.

3. The mass transfer device according to claim 1, wherein the coaxial focusing structure is used to focus a laser beam propagating in the optical fiber at a point on a substrate carrying LEDs to be lifted off.

4. The mass transfer device according to claim 3, wherein the outer side of the coaxial focusing structure is provided with a first supporting rod and a second supporting rod perpendicular to each other, a telescopic sliding rod is connected to a tail end of the second supporting rod, one end of the telescopic sliding rod is vertically fixed with the second supporting rod, and the other end of the telescopic sliding rod is vertically fixed with a rotating rod of a motor.

5. The mass transfer device according to claim 4, wherein the telescopic sliding rod comprises a telescopic driving assembly, and the length of the telescopic sliding rod is adjusted through the telescopic driving assembly.

6. The mass transfer device according to claim 4, further comprising: a processor, wherein the laser, the telescopic sliding rod and the motor are connected to the processor respectively;
the processor is configured to send a first scanning signal to the motor to control a rotating speed of the motor through the first scanning signal;
the processor is further configured to send a second scanning signal to the telescopic sliding rod to adjust the length of the telescopic sliding rod through the second scanning signal, so as to adjust a spiral rotation radius of the coaxial focusing structure; and
the processor is further configured to send a laser pulse signal to the laser to control the laser to emit a laser light through the laser pulse signal.

7. The mass transfer device according to claim 1, wherein the laser is an electrically controlled laser.

8. A mass transfer method based on a mass transfer device comprising: a laser, a coupling unit, an optical fiber, a ceramic ferrule, and a coaxial focusing structure which are sequentially connected, wherein a laser light output by the laser is coupled into the optical fiber through the coupling unit, the coaxial focusing structure is fixed to an end of the ceramic ferrule, and an end of the optical fiber is inserted into the ceramic ferrule, comprising:
sending a first scanning signal to a motor of the mass transfer device, and controlling a rotating speed of the motor through the first scanning signal;
sending a second scanning signal to a telescopic sliding rod of the mass transfer device, and adjusting a spiral rotation radius of the coaxial focusing structure in the mass transfer device through the second scanning signal; and
sending a laser pulse signal to the laser of the mass transfer device in cooperation with the first scanning signal, and controlling the laser to emit the laser light through the laser pulse signal.

9. The mass transfer method according to claim 8, wherein the coupling unit comprises a lens assembly, wherein the lens assembly is an assembly composed of one or more lenses.

10. The mass transfer method according to claim 8, wherein the coaxial focusing structure is used to focus a laser beam propagating in the optical fiber at a point on a substrate carrying LEDs to be lifted off.

11. The mass transfer method according to claim 10, wherein the outer side of the coaxial focusing structure is provided with a first supporting rod and a second supporting rod perpendicular to each other, the telescopic sliding rod is connected to a tail end of the second supporting rod, one end of the telescopic sliding rod is vertically fixed with the second supporting rod, and the other end of the telescopic sliding rod is vertically fixed with a rotating rod of the motor.

12. The mass transfer method according to claim 11, wherein the telescopic sliding rod comprises a telescopic driving assembly, and the length of the telescopic sliding rod is adjusted through the telescopic driving assembly.

13. The mass transfer method according to claim 11, further comprising: a processor, wherein the laser, the telescopic sliding rod and the motor are connected to the processor respectively;
the processor is configured to send the first scanning signal to the motor to control the rotating speed of the motor through the first scanning signal;
the processor is further configured to send the second scanning signal to the telescopic sliding rod to adjust the length of the telescopic sliding rod through the second scanning signal, so as to adjust the spiral rotation radius of the coaxial focusing structure; and
the processor is further configured to send the laser pulse signal to the laser to control the laser to emit the laser light through the laser pulse signal.

14. The mass transfer method according to claim 8, wherein the laser is an electrically controlled laser.

15. The mass transfer method according to claim 8, wherein adjusting the spiral rotation radius of the coaxial focusing structure in the mass transfer device through the second scanning signal comprises:
controlling a telescopic driving assembly of the telescopic sliding rod to telescopically move through the second scanning signal, driving the telescopic sliding rod to slide, and adjusting the spiral rotation radius of the coaxial focusing structure in the mass transfer device.

16. The mass transfer method according to claim 12, wherein adjusting the spiral rotation radius of the coaxial focusing structure in the mass transfer device through the second scanning signal comprises:
controlling the telescopic driving assembly of the telescopic sliding rod to telescopically move through the second scanning signal, driving the telescopic sliding rod to slide, and adjusting the spiral rotation radius of the coaxial focusing structure in the mass transfer device.

17. The mass transfer method according to claim 8, wherein after controlling the laser to emit the laser light through the laser pulse signal, the method further comprises:
coupling the laser light through the coupling unit of the mass transfer device, and transmitting the coupled laser light into the optical fiber of the mass transfer device; and
focusing a laser beam propagating in the optical fiber on a substrate carrying LEDs to be lifted off through the coaxial focusing structure of the mass transfer device.

18. A non-transitory computer readable storage medium storing a computer program which, when executed by a processor, causes the processor to:
send a first scanning signal to a motor of the mass transfer device comprising a laser, a coupling unit, an optical fiber, a ceramic ferrule, and a coaxial focusing structure which are sequentially connected, wherein a laser light output by the laser is coupled into the optical fiber through the coupling unit, the coaxial focusing structure is fixed to an end of the ceramic ferrule, and an end of the optical fiber is inserted into the ceramic ferrule, and control a rotating speed of the motor through the first scanning signal;
send a second scanning signal to a telescopic sliding rod of the mass transfer device, and adjust a spiral rotation radius of the coaxial focusing structure in the mass transfer device through the second scanning signal; and
send a laser pulse signal to the laser of the mass transfer device in cooperation with the first scanning signal, and control the laser to emit the laser light through the laser pulse signal.

19. The non-transitory computer readable storage medium of claim 18, wherein the computer program executed by the processor to adjust the spiral rotation radius of the coaxial focusing structure in the mass transfer device through the second scanning signal is executed by the processor to:
control a telescopic driving assembly of the telescopic sliding rod to telescopically move through the second scanning signal, drive the telescopic sliding rod to slide, and adjust the spiral rotation radius of the coaxial focusing structure in the mass transfer device.

20. The non-transitory computer readable storage medium of claim 18, wherein the computer program when executed by the processor further causes the processor to:
couple the laser light through the coupling unit of the mass transfer device, and transmit the coupled laser light into the optical fiber of the mass transfer device; and
focus a laser beam propagating in the optical fiber on a substrate carrying LEDs to be lifted off through the coaxial focusing structure of the mass transfer device.
